(19) United States
(12) Patent Application Publication
(10) Pub. No.: US 2026/0181906 A1
(43) Pub. Date: Jun. 25, 2026

(54) DIPOLE POLARIZATION-CHARGE CAPTURE SYNERGETIC SINGLE-POLARITY DRIVEN SYNAPSE TRANSISTOR AND ARTIFICIAL SENSORY SYSTEM COMPRISING THE SAME

(71) Applicant: KOREA ADVANCED INSTITUTE OF SCIENCE AND TECHNOLOGY, Daejeon (KR)

(72) Inventors: Sung Gap IM, Daejeon (KR); Sukwon JANG, Daejeon (KR); Chungryeol LEE, Daejeon (KR); Taehyun NAM, Daejeon (KR)

(73) Assignee: KOREA ADVANCED INSTITUTE OF SCIENCE AND TECHNOLOGY, Daejeon (KR)

(21) Appl. No.: 19/421,173

(22) Filed: Dec. 16, 2025

(30) Foreign Application Priority Data
Dec. 20, 2024 (KR) 10-2024-0193239

(51) Int. Cl. H10B 51/30

(52) U.S. Cl. CPC H10B 51/30

(57) ABSTRACT

The present disclosure provides a single-polarity driven synaptic utilizing synergistic effects of dipolar polarization and charge capturing, and an artificial sensory system using the same. More particularly, the present disclosure may provide a single-polarity driven synaptic transistor configured to adjust a composition of a monomer included in the dipolar polarization layer, a thickness of a gate insulating layer, and a pulse width to implement excitatory postsynaptic current (EPSC) and/or inhibitory postsynaptic current (IPSC) by adjusting a gate voltage only without changing a sign of the voltage, and emulating biological synapse, and an artificial sensory system including the same.

### CROSS-REFERENCE TO RELATED APPLICATION

The present application claims priority to and the benefit of Korean Patent Application No. 10-2024-0193239, filed on Dec. 20, 2024, in the Korean Intellectual Property Office, and all the benefits accruing therefrom under 35 U.S.C § 119, the contents of which are incorporated herein in its entirety by reference.

### BACKGROUND

### 1. Field

The present disclosure relates to a dipolar polarization-charge capture synergetic single polarity driven synaptic transistor and an artificial sensory system including the same.

### 2. Description of the Related Art

There is a growing demand for robots capable of dynamically perceiving external stimuli and responding appropriately, similar to humans, for implementation of human-machine interfaces and healthcare system.

The artificial sensory system consisting of humanoid robotics are implemented by integration of sensors, voltage and current amplifiers, excitatory and inhibitory synapse circuits, and actuators. Among these, emulating biological synapses, which are responsible for sensory perception as well as parallel information processing and storage in the nervous system, would be essential. Since external physical stimuli exhibit single polarity, it is necessary to develop artificial synaptic devices that generate excitatory and inhibitory responses depending on the amplitude of the stimuli. Through the single-polarity driven artificial synapses, it is possible to implement advanced artificial sensory systems responding continuously and dynamically to the physical stimuli. Therefore, further research on single-polarity driven synaptic devices is of great importance.

Meanwhile, the characteristics of the biological synapses may be emulated using synaptic transistors that utilize variations in drain current by adjusting a charge hole concentration in the semiconductor channel layer. By applying bipolar gate voltages to the gate of the synaptic transistor, charge holes of the semiconductor channel layer may be accumulated or depleted, thereby emulating the excitatory or inhibitory postsynaptic currents of the biological synapses.

However, synaptic transistors configured to continuously receive physical stimuli and generate postsynaptic currents in opposite directions depending on a magnitude of the stimuli have not been sufficiently advanced. Moreover, the insulating film performance required to operate without gate leakage even under strong electric fields have not been adequately realized, resulting in a lack of guaranteed stability and reliability over numerous repeated cycles.

As background technology of the present disclosure, Korean Publication No. 10-2013-0093322 discloses a single-electron synapse circuit-based neuromorphic system operating at room temperature.

### SUMMARY

An object of the present disclosure is to provide an insulating layer operating without gate leakage current even under a strong electric field.

Another object of the present disclosure is to provide an advanced artificial synaptic transistor capable of continuously receiving physical stimuli and generating opposite postsynaptic currents depending on an intensity of the stimuli.

Yet another object of the present disclosure is to provide an advanced artificial synaptic transistor capable of stably operating even under repeated cycling.

Even yet another object of the present disclosure is to provide an artificial sensory system capable of omitting one of two inverter circuits, each including a synaptic device for generating excitatory and inhibitory postsynaptic currents.

It shall be clearly construed by those of ordinary skill in the art to which the present disclosure pertains that aspects of the present disclosure are not limited to the description, and other undescribed technical objects may be clearly understood from the description and appreciated by those of ordinary skill in the art to which the present disclosure pertains.

According to one aspect, a junction gate insulating layer may be provided, the junction gate insulating layer including a dipolar polarization layer capable of polarization alignment and a charge capturing layer formed on one side of the dipolar polarization layer and configured to capture a hole or an electron.

According to one embodiment, the dipolar polarization layer may be formed of a ferroelectric material.

According to one embodiment, the dipolar polarization layer may be selected from polyvinylidene fluoride (PVDF), and a copolymer thereof, or polymers including a hydroxyl group (—OH) or a nitrile group (—CN).

According to one embodiment, the dipolar polarization layer may include p(HEA-co-DEGDVE), and a molar ratio of di(ethylene glycol)divinyl ether (DEGDVE):2-hydroxyethyl acrylate (HEA) included in the p(HEA-co-DEGDVE) may be 1:1 to 1:10.

According to one embodiment, a thickness of the dipolar polarization layer may be greater than or equal to 20 nm and less than or equal to 200 nm.

According to one embodiment, the charge capture layer may be selected from poly(1,3,5-trimethyl-1,3,5-trivinyl cyclotrisiloxane (pV3D3), poly(2-vinylnaphthalene) (PVN), polystyrene (PS), alpha-methyl styrene (PaMS), poly(divinylbenzene) (pDVB), poly(ethylene glycol dimethacrylate) (pEGDMA), poly(1,4-butanediol diacrylate) (pBDDA), poly(3,3,4,4,5,5,6,6,7,7,8,8,9,9,10,10,10-heptadecafluorodecyl methacrylate) (pPFDMA), or a combination thereof.

According to one embodiment, a thickness of the charge capture layer may be greater than or equal to 5 nm and less than or equal to 25 nm.

According to another aspect, a single-polarity driven synaptic transistor may be provided, the single-polarity driven synapse including a substrate, a gate electrode disposed on the substrate and applied with a voltage, a heterojunction gate insulating layer formed on the gate electrode, a semiconductor channel layer formed on one side of the heterojunction gate insulating layer, and a source and drain electrodes laminated on the semiconductor layer, spaced apart from each other, and having at least a portion making contact with the gate insulating layer and the semiconductor channel layer. The heterojunction gate insulating layer may include a dipolar polarization layer capable of polarization alignment and a charge capture layer formed on one side of the dipolar polarization layer and configured to capture a hole or an electron.

According to one embodiment, the dipolar polarization layer may include a ferroelectric material.

According to one embodiment, the semiconductor channel layer may be an N-type semiconductor or a P-type semiconductor.

According to one embodiment, the single-polarity driven synaptic transistor may be configured to control a voltage to be applied to the gate electrode and control flow of a hole to the drain electrode through the gate insulating layer and the semiconductor channel layer to implement excitatory postsynaptic current (EPSC) or inhibitory postsynaptic current (IPSC).

According to one embodiment, in case that a voltage of greater than or equal to −12 V and less than or equal to −3 V is applied to the gate electrode, a hole inside the semiconductor channel may be accumulated due to orientation of the dipolar polarization layer to implement excitatory postsynaptic current (EPSC), and in case that a voltage of wherein in case that a voltage of greater than or equal to −30 V and less than or equal to −20 V is applied to the gate electrode, a hole may be captured from the semiconductor channel layer into the charge capture layer or at an interface between the charge capture layer and the dipolar polarization layer to implement inhibitory postsynaptic current (IPSC).

According to one embodiment, as a pulse width applied to the gate electrode increases, both increase and decrease in conductivity of the semiconductor channel may increase.

According to one embodiment, a single-polarity driven repetitive cycle may be formed, the single-polarity driven repetitive cycle operating stably even during repeated cycles of electrical pulses applied to the gate electrode.

According to another aspect, an artificial sensory system including a single-polarity driven synaptic transistor of the present disclosure is provided.

According to one embodiment, a dipolar conjunction gate insulating layer of the present disclosure may be configured to induce accumulation or depletion of holes in the semiconductor layer within different voltage ranges, respectively, due to synergistic effect of dipolar polarization and charge capturing.

According to one embodiment, the single-polarity driven synaptic transistor including a heterojunction gate insulating layer of the present disclosure may be configured to adjust a magnitude of the gate voltage without changing a polarity of the voltage to implement an excitatory postsynaptic current (EPSC) or an inhibitory postsynaptic current (IPSC).

According to one embodiment, a single-polarity driven synaptic transistor including a heterojunction gate insulating layer of the present disclosure may operate without gate leakage even under a strong electric field.

According to one embodiment, an advanced single-polarity driven synaptic transistor of the present disclosure may operate stably even under repeated cycles and secure stability and reliability.

According to one embodiment, an artificial sensory system including a single-polarity driven synaptic transistor of the present disclosure may be implemented with only a single inverter circuit.

According to one embodiment, a single-polarity driven synaptic transistor of the present disclosure may be included to provide an advanced artificial sensory system emulating biological synaptic characteristics that continuously and dynamically respond to physical stimuli.

### BRIEF DESCRIPTION OF THE DRAWINGS

The accompanying drawings are included to provide a further understanding of the present disclosure and are incorporated in and constitute a part of this disclosure. The drawings illustrate embodiments of the present disclosure and, together with the description, serve to explain principles of the disclosure. These and/or other features will become apparent and more readily appreciated from the following description of one or more embodiments, taken in conjunction with the accompanying drawings, in which:

(a) in FIG. 1 and (b) in FIG. 1 are a schematic view of a single-polarity driven synaptic transistor structure including a heterojunction gate insulating layer according to Embodiment 1 of the present disclosure;

FIG. 2 illustrates electrical characteristics of a single-polarity driven synaptic transistor according to one embodiment of the present disclosure;

(a) in FIG. 3 and (b) in FIG. 3 are a schematic view of an operating mechanism of an excitatory postsynaptic current (EPSC) implemented by a single-polarity driven synaptic transistor according to one embodiment of the present disclosure under application of a low voltage;

(a) in FIG. 4 and (b) in FIG. 4 are an schematic view of an operating mechanism of an inhibitory postsynaptic current (IPSC) implemented by a single-polarity driven synaptic transistor according to one embodiment of the present disclosure under application of a high voltage;

(a) in FIG. 5 through (c) in FIG. 5 illustrate synaptic characteristics of a single-polarity driven synaptic transistor according to one embodiment of the present disclosure, depending on a composition of 2-hydroxyethyl acrylate (HEA) in a dipolar polarization layer;

FIG. 6 illustrates a measured value of a dielectric constant of a dipolar polarization layer of a single-polarity driven synaptic transistor according to one embodiment depending on a composition of 2-hydroxyethyl acrylate (HEA) in a dipolar polarization layer;

(a) in FIG. 7 through (c) in FIG. 7 illustrate synaptic characteristics depending on a configuration of a gate insulating layer in a single-polarity driven transistor according to one embodiment of the present disclosure;

FIG. 8 illustrates synaptic characteristics according to a pulse width of a single-polarity synaptic transistor according to one embodiment of the present disclosure;

FIG. 9 illustrates stable durability characteristics of a single-polarity driven synaptic transistor manufactured according to one embodiment of the present disclosure during repeated cycles; and

FIG. 10 illustrates Fourier transform infrared (FT-IR) spectra of a dipolar polarization layer of a single-polarity driven synaptic transistor according to one embodiment of the present disclosure depending on a composition of 2-hydroxyethyl acrylate (HEA) in the dipolar polarization layer. (1: C—OH, 2: C═O, 3: C—O of an ester group, 4: C—O of an ether group)

### DETAILED DESCRIPTION

Objects, specific advantages and novel characteristics of the present disclosure will be come more apparent from the following detailed description and embodiments in relation with the accompanying drawings.

Prior to the description, the terms and words used in the specification and claims should not be interpreted in their ordinary or dictionary meanings, but shall be construed in accordance with the technical idea of the present disclosure, based on the principle that the inventor may appropriately define the concepts of the terms to describe the invention in the best possible manner.

In the present disclosure, when an element, such as a layer, a part, or a substrate, is described as being “on,” “connected,” or “coupled to” another element, it may be directly “on,” “connected,” or “coupled to” the other element or have one or more other elements interposed between the two elements. In contrast, when an element is described as being “directly on,” “directly connected to,” or “directly coupled to” another element, no other element may be interposed between the two elements.

A terminology used in the present disclosure is utilized solely to describe specific embodiments and is not intended to limit the present disclosure. Unless clearly indicated otherwise by the context, singular expressions include their plural forms.

In the present disclosure, terms such as “include” or “have” are intended to indicate the presence of features, numbers, steps, operations, elements, parts, or combinations thereof as described in the specification, and should be understood as not precluding the presence or addition of one or more other features, numbers, steps, operations, elements, parts, or combinations thereof.

In the present disclosure, when a part is described as “including” a certain part, other elements may also be included, unless explicitly stated otherwise. Furthermore, throughout the entire specification, the term “on” refers to being located above or below a subject and does not necessarily indicate a position relative to the gravitational direction.

The present disclosure may be variously modified and have various embodiments. Specific embodiments are illustrated in the drawings and described in detail in the detailed description. However, this is not intended to limit the disclosure to any particular form, and it should be understood to include all modifications, equivalents, or alternatives within the idea and scope of the present disclosure. In explaining the present disclosure, detailed descriptions of related known technologies are omitted where they may obscure the gist of the present disclosure.

Hereinafter, embodiments of the present disclosure will be described with reference to the accompanying drawings in detail, and in describing with reference to the accompanying drawings, identical or corresponding elements will be designated with the same reference numerals, and redundant descriptions thereof will be omitted.

(a) in FIG. 1 and (b) in FIG. 1 are a schematic view of a single-polarity driven synaptic transistor structure including a heterojunction gate insulating layer according to Embodiment 1 of the present disclosure. Referring to (a) in FIG. 1 and (b) in FIG. 1, a single-polarity driven synaptic transistor 1 of the present disclosure may include a heterojunction gate insulating layer 30, and the heterojunction gate insulating layer 30 may have a structure including a dipolar polarization layer 32 capable of polarization alignment, and a charge capture layer 34 formed on one side of the dipolar polarization layer and configured to capture a hole or an electron.

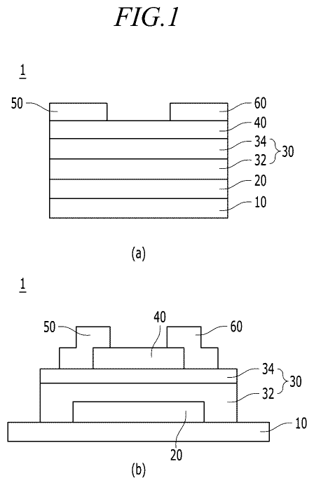

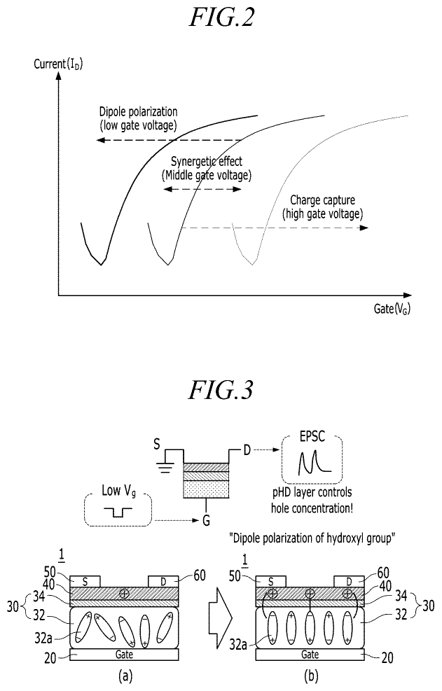

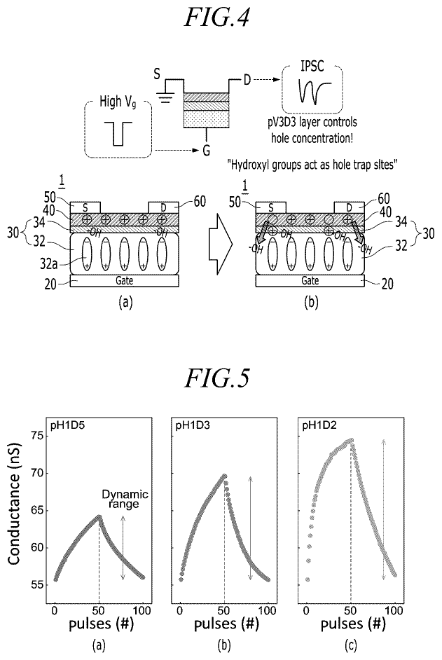

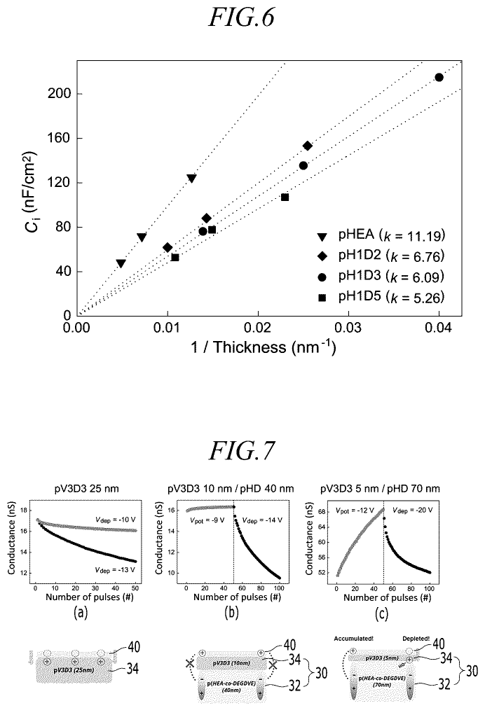

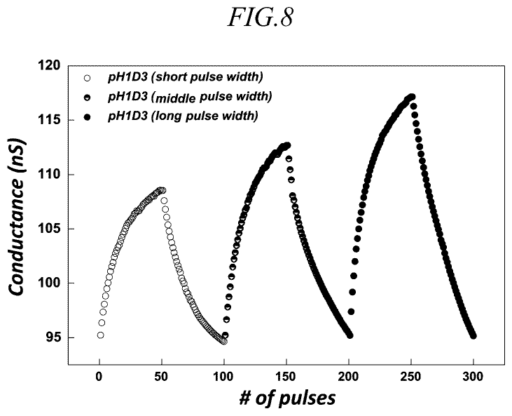

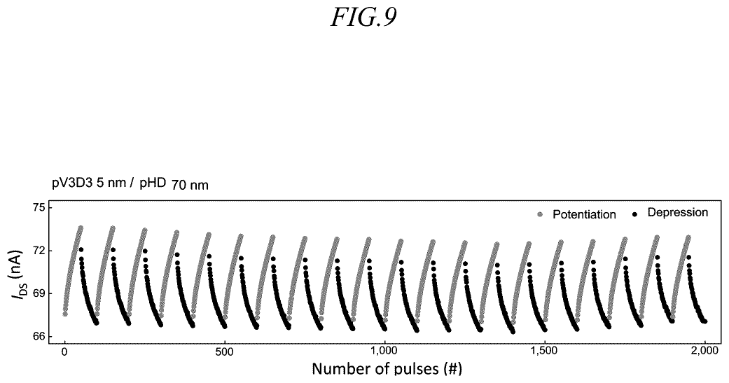

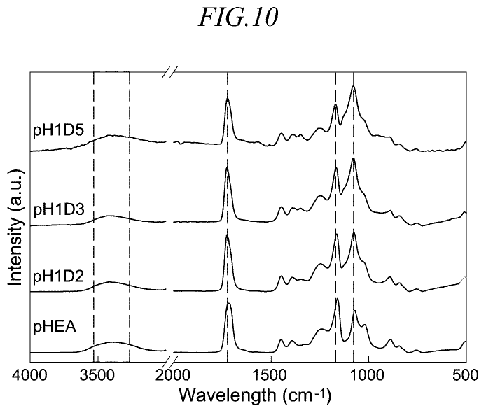

FIG. 2 illustrates electrical characteristics of a single-polarity driven synaptic transistor according to one embodiment of the present disclosure. Referring to FIG. 2, the dipolar polarization layer and the charge capture layer of the heterojunction gate insulating layer exhibit a synergistic effect to implement a single-polarity driven artificial synapse. Particularly, upon applying a voltage, a charge capture layer configured to capture a hole and a dipolar polarization layer capable of polarization alignment may be vertically laminated to form a heterojunction gate insulating layer, and a hole or electron may be laminated in a semiconductor channel layer 40 in different voltage ranges, respectively, or depletion of a hole or electron may be induced to implement an excitatory postsynaptic current (EPSC) or an inhibitory postsynaptic current (IPSC).

A conventional artificial sensory system required two inverter circuits including a synaptic device to generate both excitatory and inhibitory postsynaptic current. However, a single-polarity driven synaptic transistor of the present disclosure may omit one inverter circuit and still implement synaptic characteristics by synergistic effects of the heterojunction gate insulating layer that performs opposing functions. That is, an artificial sensory system including a single-polarity driven synaptic transistor of the present disclosure may be capable of generating both excitatory and inhibitory postsynaptic current using only a single inverter circuit.

(a) in FIG. 3 through (b) in FIG. 4 are schematic views of an operating mechanism of an excitatory postsynaptic current (EPSC) implemented by a single-polarity driven synaptic transistor according to one embodiment of the present disclosure under application of a low voltage, and an operating mechanism of an inhibitory postsynaptic current (IPSC) implemented by a single-polarity driven synaptic transistor according to one embodiment of the present disclosure under application of a high voltage. For reference, (a) in FIG. 3 through (b) in FIG. 4 include a semiconductor channel layer of a P-type semiconductor. Referring to (a) in FIG. 3 and (b) in FIG. 3, upon applying a gate voltage of a low amplitude to a single-polarity driven synaptic transistor (1 in (a)), holes may be accumulated in the semiconductor channel layer (40 in (b)) by orientation of charged functional groups in the dielectric material 32a in the dipolar polarization layer (32 in (b)) to implement an EPSC. Furthermore, referring to (a) in FIG. 4 and (b) in FIG. 4, upon applying a gate voltage of a high amplitude to a single-polarity driven synaptic transistor (1 in (a)) of the present disclosure, a hole may be captured in a charge capture layer (34 in (b)) or at an interface between the charge capture layer (34 in (b)) and dipolar polarization layer (32 in (b)) from the semiconductor channel layer (40 in (b))), and a hole may be depleted to implement an IPSC.

The mechanism may be formed with different types of charges depending on a type of a semiconductor used in the semiconductor channel layer (40 in (b)). Particularly, in case that the semiconductor channel layer (40 in (b)) is a P-type semiconductor, a hole may be captured in the charge capture layer (34 in (b)) or at an interface between the charge capture layer (34 in (b)) and the dipolar polarization layer (32 in (b)) from the semiconductor channel layer (40 in (b)) to implement an IPSC, and in case that the semiconductor channel layer (40 in (b)) is an N-type semiconductor, an electron may be captured in the charge capture layer (34 in (b)) or at an interface between the charge capture layer (34 in (b)) and the dipolar polarization layer (32 in (b)) to implement an IPSC.

In addition, in case that the semiconductor channel layer is a P-type semiconductor, a hole may be accumulated inside the semiconductor channel layer (40 in (b)) to implement an EPSC, and in case that the semiconductor layer is an N-type semiconductor, an electron may be accumulated in the semiconductor channel layer (40 in (b)) to implement an EPSC.

Although the present disclosure is not limited thereto, the dipolar polarization layer 32 may be formed of a ferroelectric material. The ferroelectric material may refer to a material whose polarization direction can be switched by an external electric field and may be selected from poly(vinylidene fluoride) (PVDF) and a copolymer thereof, or a polymer including a hydroxyl group (—OH) or a nitrile group (—CN), but the present disclosure is not limited thereto. The poly(vinylidene fluoride) (PVDF) and a copolymer thereof may be selected from poly(vinylidene fluoride-co-trifluoroethylene) p(VDF-TrFE), poly(vinylidene fluoride-trifluoroethylene-chlorofluoroethylene) (p(VDF-TrFE-CFE)), and poly(vinylidene fluoride-co-chlorotrifluoroethylene) p(VDF-CTFE), but the present disclosure is not limited thereto. In addition, the polymer including a hydroxyl group (—OH) or a nitrile group (—CN) may be selected from poly(vinyl alcohol) (PVA), polyacrylonitrile (PAN), poly(2-hydroxyethylacrylate) (pHEA), poly(2-cyanoethyl acrylate) (pCEA) and a copolymer thereof, but the present disclosure is not limited thereto.

A material consisting of the dipolar polarization layer 32 may suitably be p(HEA-co-DEGDVE), but the present disclosure is not limited thereto. The p(HEA-co-DEGDVE) may be may be a copolymer of 2-hydroxyethylacrylate (HEA) and di(ethyleneglycol)divinylether (DEGDVE) monomers, and may be represented by Formula 1:

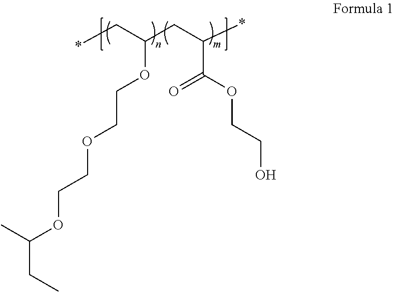

The ^{—}* indicates a bonding site to Formula 1.

(a) in FIG. 5 through (c) in FIG. 5 illustrate synaptic characteristics of a single-polarity driven synaptic transistor depending on a composition of 2-hydroxyethylacrylate (HEA) in a dipolar polarization layer according to one embodiment of the present disclosure. Here, the pH1D2, pH1D3 and pH1D5 shown in (a) in FIG. 5 through (c) in FIG. 5 refer to p(HEA-co-DEGDVE) polymers with different molar ratios of 2-hydroxyethylacrylate (HEA):di(ethylglycol)divinylether (DEGDVE). The molar ratio may be controlled by adjusting a flow rate ratio of 2-hydroxyethylacrylate (HEA) with respect to di(ethyleneglycol)divinyl. Although the present disclosure is not limited thereto, the molar ratio may refer to a composition ratio.

Particularly, a flow rate ratio of 2-hydroxyethylacrylate (HEA):di(ethyleneglycol)divinylether (DEGDVE) in the PH1D2 may be 1:2. When this is expressed in terms of a molar ratio, a molar ratio of 2-hydroxyethylacrylate (HEA):di(ethyleneglycol)divinylether (DEGDVE) may be represented as 2.2:1. The flow rate ratio of 2-hydroxyethylacrylate (HEA):di(ethyleneglycol)divinylether (DEGDVE) in the pH1D3 may be 1:3. When this is expressed in terms of a molar ratio, a molar ratio of 2-hydroxyethylacrylate (HEA):di(ethyleneglycol)divinylether (DEGDVE) may be represented as 1.7:1. A flow rate of 2-hydroxyethylaacrylate (HEA):di(ethyleneglycol)divinylether (DEGDVE) in the pH1D5 may be 1:5. When this is expressed in a molar ratio, a molar ratio of 2-hydroxyethylacrylate (HEA):di(ethyleneglycol)divinylether (DEGDVE) may be represented as 1.5:1.

Referring to (a) in FIG. 5 through (c) in FIG. 5, as a molar ratio of a 2-hydroxyethylacrylate (HEA) monomer increases, the effects of accumulating a hole or electron, effects capturing a hole or electron, or both of accumulating a hole or electron and capturing a hole or electron by a hydroxyl group inside the 2-hydroxyethylacrylate (HEA) may be promoted. Therefore, when a molar ratio of the 2-hydroxyethylacrylate (HEA) monomer in the p(HEA-co-DEGDVE) polymer increases, both increase and decrease in semiconductor channel layer conductivity may increase, thereby expanding an adjustable range of conductivity. Accordingly, when a molar ratio of the 2-hydroxyethylacrylate (HEA) monomer is adjusted, conductivity may be adjusted over a wider range even with a same number of pulses.

In addition, a molar ratio of a monomer of di(ethyleneglycol)divinylether (DEGDVE) may be adjusted to control a degree of insulation.

In the p(HEA-co-DEGDVE) polymer, a molar ratio of di(ethyleneglycol)divinylether (DEGDVE):2-hydroxyethylacrylate (HEA) included in the p(HEA-co-DEGDVE) may be 1:1 to 1:10, 1:2 to 1:8, 1:2 to 1:6, or 1:2 to 1:4. In case that a molar ratio of di(ethyleneglycol)divinylether (DEGDVE):2-hydroxyethylacrylate (HEA) included in the p(HEA-co-DEGDVE) is less than 1:1, it may be difficult to appropriately implement accumulation effect of a hole or electron and/or capturing effect of a hole or electron due to the hydroxyl group, and in case that the molar ratio of the 2-hydroxyethylacrylate (HEA) exceeds 1:10, insulation properties of the p(HEA-co-DEGDVE) polymer may be insufficient. Although the present disclosure is not limited thereto, considering accumulation effect of a hole or electron and/or capturing effect of a hole or electron as well as improvement of insulation properties, a molar ratio of di(ethyleneglycol)divinylether (DEGDVE):2-hydroxyethylacrylate (HEA) may suitably be 1:2 to 1:6, and more suitably be 1:2 to 1:4.

FIG. 6 illustrates a measured value of a dielectric constant of a dipolar polarization layer of a single-polarity driven synaptic transistor according to one embodiment depending on a composition of 2-hydroxyethyl acrylate (HEA) in a dipolar polarization layer. Referring to FIG. 6, by adjusting a molar ratio of 2-hydroxyethylacrylate (HEA) in a dipolar polarization layer according to the present disclosure, a dielectric constant may be adjusted to increase electrical reliability and reduce leakage current while conductivity can be adjusted to a wider range. The pHEA described in FIG. 6 may represent poly(2-hydroxyethylacrylate) (pHEA), and pH1D2, pH1D3, and pH1D5 may be as described in (a) in FIG. 5 through (c) in FIG. 5.

(a) in FIG. 7 through (c) in FIG. 7 illustrate synaptic characteristics depending on a configuration of a gate insulating layer in a single-polarity driven transistor according to one embodiment of the present disclosure. Referring to (a) in FIG. 7 through (c) in FIG. 7, it can be confirmed that artificial synaptic characteristics cannot be implemented when an insulating layer consisting of a charge capture layer only is present, and that artificial synaptic characteristics can be implemented only when both a dipolar polarization layer and a charge capture layer are formed. Furthermore, thicknesses of the dipolar polarization layer and the charge capture layer in the heterojunction gate insulating layer of the present disclosure may be appropriately adjusted to suitably implement EPSC and IPSC and improve artificial synaptic characteristics.

Although the present disclosure is not limited thereto, a thickness of the dipolar polarization layer may be greater than or equal to 20 nm and less than or equal to 200 nm. Although the present disclosure is not limited thereto, it may suitably be greater than or equal to 25 nm and less than or equal to 180 nm, greater than or equal to 30 nm and less than or equal to 150 nm, or greater than or equal to 40 nm and less than or equal to 100 nm. Although the present disclosure is not limited thereto, in case that a thickness of the dipolar polarization layer is less than 20 nm, insulation may be insufficient, and in case that a thickness of the dipolar polarization layer is greater than 200 nm, it may be difficult to suitably implement accumulation effect of a hole or electron and/or capturing effect of a hole or electron through the dipolar polarization layer.

Although the present disclosure is not limited thereto, due to the high breakdown voltage characteristics of the charge capture layer, the single-polarity driven synaptic transistor of the present disclosure may operate stably even under repetitive cycles of gate pulses with varying low and high amplitudes. Although the present disclosure is not limited thereto, the charge capture layer of the present disclosure may have a breakdown voltage of greater than or equal to 4 MV/cm.

FIG. 9 illustrates stable durability characteristics of a single-polarity driven synaptic transistor manufactured according to one embodiment of the present disclosure during repeated cycles. Referring to FIG. 9, due to the synergistic effects of the charge capture layer and the dipolar polarization layer in the heterojunction gate insulating layer of the present disclosure, the single-polarity driven synaptic transistor of the present disclosure may operate stably even under repetitive cycles without leakage current.

Although the present disclosure is not limited thereto, the charge capture layer may be selected from poly(1,3,5-trimethyl-1,3,5-trivinyl cyclotrisiloxane (pV3D3), poly(2-vinylnaphthalene)(PVN), polystyrene (PS), alpha-methyl styrene (PαMS), poly(divinylbenzene) (pDVB), poly(ethylene glycol dimethacrylate) (pEGDMA), poly(1,4-butanediol diacrylate) (pBDDA), poly(3,3,4,4,5,5,6,6,7,7,8,8,9,9,10,10,10-heptadecafluorodecylmethacrylate) (pPFDMA), or a combination thereof, and suitably be poly(1,3,5-trimethyl-1,3,5-trivinyl cyclotrisiloxane (pV3D3).

A material constituting the charge capture, poly(1,3,5-trimethyl-1,3,5-trivinyl cyclotrisiloxane (pV3D3) may be represented by Formula 2:

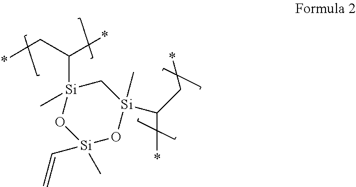

The ^{—}* indicates a bonding site of Formula 2.

Although the present disclosure is not limited thereto, a thickness of the charge capture layer may be greater than or equal to 1 nm and less than or equal to 40 nm, and suitably be greater than or equal to 5 nm and less than or equal to 25 nm. Although the present disclosure is not limited thereto, in case that a thickness of the charge capture layer is less than 1 nm or greater than 40 nm, it may be difficult to achieve capturing effects of a hole or electron, and improved durability allowing stable operation of the single-polarity driven synaptic transistor during repetitive cycles.

According to another aspect of the present disclosure, a single-polarity driven synaptic transistor including the heterojunction gate insulating layer of the present disclosure is provided.

Referring to (a) in FIG. 1 and (b) in FIG. 1 schematically illustrating a single-polarity driven synaptic transistor having a structure including a heterojunction gate insulating layer according to Embodiment 1, the single-polarity driven synaptic transistor 1 of the present disclosure may include a substrate 10, a gate electrode 20 disposed on the substrate and receiving a voltage, a heterojunction gate insulating layer 30 formed on the gate electrode, a semiconductor channel layer 40 formed on the heterojunction gate insulating layer 30, and a source electrode 50 and a drain electrode 60 laminated on the semiconductor channel layer 40, spaced apart from each other, and having at least a portion making contact with the gate insulating layer and the semiconductor channel layer. As described above, the heterojunction gate insulating layer 30 may include a dipolar polarization layer 32 capable of polarity orientation, and a charge capture layer 34 formed on one side of the dipolar polarization layer and configured to capture a hole or electron.

The substrate 10 may be formed of various known substrate materials and may not be particularly limited as long as it is suitable for implementing a single-polarity driven synaptic transistor. Although the present disclosure is not limited thereto, the substrate 10 may include, for example, glass, ceramic, metal, or polymer resin, such as polyimide, include an inorganic layer, an organic layer, and a composite material layer, and be formed as a single layer or a multilayer structure. Examples of the polymer resin may be selected from polystyrene (PS), polyimide (PI), poly(methylmethacrylate) (PMMA), polyurethane (PU), poly(vinylalcohol), poly(4-vinylphenol) (PVP), and poly(vinyl chloride) (PVC), and poly(vinylidene fluoride) (PVDF), but the present disclosure is not limited thereto.

The gate electrode 20 disposed on the substrate 10 and configured to receive a voltage, the source electrode 50 and the drain electrode 60 may include a metallic material and a metal oxide layer, respectively, and be formed of various known electrode materials, and may not be particularly limited as long as it is to implement a single-polarity driven synaptic transistor of the present disclosure. For example, the metallic material may be selected from a group consisting of Al, Ag, Au, Cr, Pt, Mo, Ni, Ti, Cu, Hf, Zr, Ta, Ru, W, Co, Fe and Pb, and the metal oxide layer may be selected from a group consisting of MoO₃, NiO, CoO and TiO₂, but the present disclosure is not limited thereto.

The heterojunction gate insulating layer 30 formed on the gate electrode may include a dipolar polarization layer 32 capable of polarity orientation and a charge capture layer 34 formed on one side of the dipolar polarization layer and configured to capture a hole or electron. The dipolar polarization layer 32 and the charge capture layer 34 may be provided with the same characteristics as described above, and therefore, detailed descriptions thereof will be omitted.

A single-polarity driven synaptic transistor 1 including the heterojunction gate insulating layer 30 of the present disclosure may be configured to control a voltage applied to the gate electrode 20 and control accumulation and depletion of a hole in the semiconductor channel layer 40 to implement excitatory postsynaptic current (EPSC) or inhibitory postsynaptic current (IPSC).

Although the present disclosure is not limited thereto, the semiconductor channel layer 40 may be an N-type semiconductor or a P-type semiconductor. The N-type semiconductor or the P-type semiconductor may be formed of various known inorganic or organic materials, and may not be particularly limited as long as it is suitable for implementing the single-polarity driven synaptic transistor 1 of the present disclosure.

The single-polarity driven synaptic transistor 1 of the present disclosure, which emulates biological synapses, may operate based on an intensity and/or frequency of the voltage. In this case, the semiconductor channel layer 40 may be configured to control flow of current and information and advantageous in implementation of the transistor's variable characteristics. In addition, although the present disclosure is not limited thereto, in case that a P-type semiconductor is used in the semiconductor channel layer 40, connection and compatibility with other devices may be facilitated. In case that coupling with an N-type semiconductor is required, a P-N junction may be formed to facilitate improvement of performance of a single-polarity driven synaptic transistor and optimization of electric characteristics. The P-type semiconductor may be suitable in a conventional semiconductor manufacturing technologies, operate stably at room temperature, and increase device reliability, but the present disclosure is not limited thereto. In addition, in case that an N-type semiconductor is used, due to its high electron mobility, it may be advantageous for implementing high-efficiency devices capable of high-speed operation, but the present disclosure is not limited thereto.

The single-polarity driven synaptic transistor 1 has an advantage of controlling conductivity of the semiconductor channel layer 40 by controlling magnitude of a voltage applied to the gate electrode 20 without changing a sign of the gate voltage.

The single-polarity driven synaptic transistor 1 of the present disclosure may control a voltage applied to the gate electrode 20 to control flow of a hole to the drain electrode through the gate insulating layer 30 and the semiconductor channel layer 40 and implement excitatory postsynaptic current (EPSC) or inhibitory postsynaptic current (IPSC). Although the present disclosure is not limited thereto, in case that a voltage of greater than or equal to −12 V and less than or equal to −3 V is applied to the gate electrode 20, a hole may be accumulated in the semiconductor channel layer 40 due to orientation of the dipolar polarization layer 32 to generate excitatory postsynaptic current (EPSC). In addition, in case that a voltage of greater than or equal to −30 V and less than or equal to −20 V is applied to the gate electrode 20, a hole may be captured in the charge capture layer or at an interface between the charge capture layer or the dipolar polarization layer from the semiconductor channel layer 40 to generate inhibitory postsynaptic current (IPSC). Although the present disclosure is not limited thereto, a voltage of the gate electrode 20 to generate the excitatory postsynaptic current (EPSC) or inhibitory postsynaptic current (IPSC) may vary depending on a type and thickness of the dipolar polarization layer and the charge capture layer. Particularly, a voltage of the gate electrode 20 to generate EPSC or IPSC tends to decrease as a dipole moment of molecules consisting of the dipolar polarization layer increases and as a thickness of the dipolar polarization layer and a thickness of the charge capture layer becomes thinner.

Although the present disclosure is not limited thereto, a pulse width applied to the gate electrode 20 may be adjusted to control conductivity of the semiconductor channel layer 40. FIG. 8 illustrates synaptic characteristics according to a pulse width of a single-polarity synaptic transistor according to one embodiment of the present disclosure. Referring to FIG. 8, by increasing a pulse width applied to the gate electrode in the same single-polarity driven synaptic transistors provided with a dipolar polarization layer including pH1D3, both the increase and decrease in conductivity of the semiconductor channel layer may increase. This indicates that an adjustable range of conductivity variation in the semiconductor channel layer may be broadened. Accordingly, a single-polarity driven transistor provided with a same heterojunction gate insulating layer as that of the present disclosure may adjust a pulse width applied to the gate electrode to improve artificial synaptic characteristics.

For the described reasons, the single-polarity driven synaptic transistor of the present disclosure may be configured to form single-polarity driven repetitive cycles in which the device operates stably even under repetitive cycles of electrical pulses applied to the gate electrode.

According to another aspect of the present disclosure, the present disclosure may provide an artificial synaptic device having a single-polarity driven synaptic transistor structure of the present disclosure, and an artificial sensory system including the same. Particularly, according to one embodiment of the present disclosure, an artificial sensory system is provided, the system integrated with at least one artificial sensory receptor sensor configured to detect stimuli and output voltage and current amplification, a synapse circuit configured to amplify the output voltage and current and implement excitatory and inhibitory functions through the amplified signal, and an actuator configured to receive an input signal from the synapse circuit and generate mechanical movement.

The artificial sensory receptor sensor may be selected from a temperature sensor, a strain sensor, a pressure sensor, an optical sensor, a visual information detection sensor, a balance detection sensor, a gyroscope sensor, and a chemical sensor of a substance in vivo or in vitro, and a combination thereof, but the present disclosure is not limited thereto.

The synaptic circuit may be characterized in that a single-polarity synaptic transistor is included, the single-polarity synaptic transistor including a heterojunction gate insulating layer including dipolar polarization layer capable of polarity orientation and a charge capture layer formed on one side of the dipolar polarization layer and configured capture a hole. Accordingly, due to the described reasons, the present disclosure may provide a stably operating, advanced artificial sensory system that operates with a single inverter circuit while enhancing artificial synaptic characteristics.

The actuator may visualize and/or convert into sound received stimuli exceeding a threshold input from each sensor or to return to a state below the threshold. Although the present disclosure is not limited thereto, for example, in case that the stimulus received through the sensor is a thermal stimulus, the actuator may be configured to determine a threshold and accumulate the thermal stimulus up to the threshold to have the stimuli visually or audibly perceived, or perform a movement to return to a thermal stimulus state below the threshold. In case that a stimuli received through the sensor is a physical or chemical stimuli, the actuator may be configured to measure an applied pressure or a concentration of gas or liquid droplet and have it visually or audibly perceived.

An artificial sensory system of the present disclosure may be configured to implement an advanced artificial sensory system configured to respond continuously and dynamically to external thermal, physical, and/or chemical stimuli. Although the present disclosure is not limited thereto, the artificial sensory system may be applied to a burn prevention system, biological change monitoring system for artificial cochlear, artificial retina, BUMPER (brain-computer interface), artificial skin, heart rate and blood pressure, disease prediction system using a biochemical substance in a body, safety system of a structure, and air quality monitoring system.

Hereinafter, the present disclosure will be described in detail with references to Embodiments.

### Embodiment

### Embodiment 1. Manufacture of a Single-Polarity Driven Synaptic Transistor (pH1D2) Including a Heterojunction Gate Insulating Layer

### 1-1) Manufacture of a Gate Electrode

A 40 nm-thick aluminum film was deposited on a substrate by vacuum thermal deposition and used as a gate electrode.

### 1-2) Manufacture of a Heterojunction Gate Insulating Layer

1-2-1) Manufacture of a Charge Capture Layer (pV3D3)

In order to manufacture a poly(1,3,5-trivinyl-1,3,5-trimethyl cyclotrisiloxane (pV3D3) polymer, vapor flows of V3D3 and TBPO were established in an iCVD reactor. Here, V3D3 and TBPO were introduced to a chamber at flow rates of 4.16 sccm and 1.46 sccm, respectively. The chamber pressure and substrate temperature were maintained at 100 mTorr and 50° C., respectively.

### 1-2-2) Manufacture of a Dipolar Polarization Layer

For deposition of p(HEA-co-DEGDVE), di(ethyleneglycol)divinylether (DEGDVE) and TBPO were introduced at flow rates of 1.10 sccm, and 0.49 sccm, respectively. A flow rate of 2-hydroxyethylacrylate (HEA) monomer was adjusted to 1.10 sccm. The chamber pressure and the substrate temperature were maintained at 70 mTorr and 30° C., respectively. 1,3,5-trimethyl-1,3,5-trivinylcyclotrisiloxane (V3D3), 2-hydroxyethylacrylate (HEA), di(ethyleneglycol)divinylether (DEGDVE) and TBPO were heated to 40° C., 45° C., 50° C. and 30° C., respectively, to facilitate evaporation. In all cases, the filament temperature was set to 130° C. to initiate polymerization.

The generated p(HEA-co-DEGDVE) was deposited on a substrate through an iCVD process. Using the iCVD, it was possible to manufacture dipolar polarization layers of various thicknesses while minimizing reduction in a dielectric constant of a copolymer. A flow ratio of di(ethyleneglycol)divinylether (DEGDVE):2-hydroxyethylacrylate (HEA) included in the dipolar polarization layer was 2:1, and a molar ratio of di(ethyleneglycol)divinylether (DEGDVE):2-hydroxyethylacrylate (HEA) could be represented as 1:2.2 when it is converted to a molar ratio (composition ratio).

Thicknesses of the dipolar polarization layer and the charge capture layer were 70 nm and 5 nm, respectively.

### 1-3) Manufacture of a Semiconductor Channel Layer, Source Electrode, and Drain Electrode

The semiconductor channel layer was vacuum-thermally deposited on the charge capture layer of the heterojunction gate insulating layer. A 5 nm MoO₃ film and 50 nm Cu thi film were sequentially vacuum-thermally deposited on the channel layer at rates of 0.1 and 1 Å s⁻¹, respectively, to form a source-drain (S-D) electrode.

### Embodiment 2. Manufacture of a Single-Polarity Driven Synaptic Transistor Including a Heterojunction Gate Insulating Layer (pH1D3)

In comparison to Embodiment 1, the manufacture was carried out in a same manner as in Embodiment 1 except for that a flow ratio of di(ethyleneglycol)divinylether (DEGDVE):2-hydroxyethylacrylate (HEA) included in the dipolar polarization layer were adjusted to 3:1, resulting in a molar ratio of di(ethyleneglycol)divinylether (DEGDVE):2-hydroxyethylacrylate (HEA) of 1:1.7.

### Embodiment 3. Manufacture of a Single-Polarity Driven Synaptic Transistor Including a Heterojunction Gate Insulating Layer (pH1D5)

In comparison to Embodiment 1, the manufacture was carried out in a same manner as in Embodiment 1 except for that a flow ratio of di(ethyleneglycol)divinylether (DEGDVE):2-hydroxyethylacrylate (HEA) included in the dipolar polarization layer were adjusted to 5:1, resulting in a molar ratio of di(ethyleneglycol)divinylether (DEGDVE):2-hydroxyethylacrylate (HEA) of 1:1.5.

### Embodiment 4. Manufacture of a Single-Polarity Driven Synaptic Transistor Including a Heterojunction Gate Insulating Layer

In comparison to Embodiment 1, the manufacture was carried out in a same manner as in Embodiment 1 except for that a thickness of the charge capture layer was 10 nm, and a thickness of the dipolar polarization layer was 40 nm.

### Manufacture 5. Manufacture of a Single-Polarity Driven Synaptic Transistor Including a Heterojunction Gate Insulating Layer

In comparison to Embodiment 1, the manufacture was carried out in a same manner as in Embodiment 1 except for that p(CEAco-DEGDVE) was included instead of the p(HEA-co-DEGDVE) in the dipolar polarization layer.

### Embodiment 6. Manufacture of a Single-Polarity Driven Synaptic Transistor Including a Heterojunction Gate Insulating Layer

In comparison to Embodiment 1, the manufacture was carried out in a same manner as in Embodiment 1 except for that p(CEA-co-BDDVE) was included instead of the p(HEA-co-DEGDVE) in the dipolar polarization layer.

### Comparative Example 1. Manufacture of a Single-Polarity Driven Synaptic Transistor Including a Single Layer of an Insulating Layer

In comparison to Embodiment 1, the manufacture was carried out in a same manner as in Embodiment 1 except for that only a charge capture layer was included in the insulating layer structure.

### Comparative Example 2. Manufacture of a Single-Polarity Driven Synaptic Transistor Including a Dipolar Polarization Layer Formed of Poly 2-Hydroxyethylacrylate (pHEA) Only

In comparison to Embodiment 1, the manufacture was carried out in a same manner as in Embodiment 1 except for that only poly 2-hydroxyethylacrylate (pHEA) was included in the dipolar polarization layer.

### Result

### Experimental Example 1. Characteristics of Artificial Synapse Depending on a Chemical Composition of a Heterojunction Gate Insulating Layer

(a) in FIG. 5 through (c) in FIG. 5 illustrate synaptic characteristics of a single-polarity driven synaptic transistor depending on a composition of 2-hydroxyethylacrylate (HEA) in a dipolar polarization layer according to one embodiment of the present disclosure. Referring to (a) in FIG. 5 through (c) in FIG. 5, it would be confirmed that as a molar ratio of 2-hydroxyethylacrylate (HEA) monomer increases, a range of adjustable conductivity could be broadened. Particularly, as a molar ratio of 2-hydroxyeethylacrylate (HEA) monomer increases in the poly(2-hydroxyethylacrylate-co-di(ethyleneglycol)divinylether) (p(HEA-co-DEGDVE)), generation of post-synaptic current in opposite directions could be modulated to a greater extent even with a same number of pulses.

In addition, as shown in FIG. 6, it was shown that as a molar ratio of 2-hydroxyethylacrylate (HEA) monomer in the poly(2-hydroxyethylacrylate-co-di(ethyleneglycol)divinylether) (p(HEA-co-DEGDVE)) increased, a dielectric constant of the heterojunction gate insulating layer increased. Accordingly, a molar ratio of 2-hydroxyethylacrylate (HEA) monomer in the poly(2-hydroxyethylacrylate-co-di(ethyleneglycol)divinylether) (p(HEA-co-DEGDVE)) was adjusted to obtain a heterojunction gate insulating layer having a dielectric constant of a desired measurement value.

### Experimental Example 2. Characteristics of Artificial Synapse Depending on a Configuration of a Heterojunction Gate Insulating Layer

(a) in FIG. 7 through (c) in FIG. 7 illustrate synaptic characteristics depending on a configuration of a gate insulating layer. Referring to (a) in FIG. 7 through (c) in FIG. 7, in case that only a charge capture layer was included ((a): Comparative Example 1), IPSC was generated at −10 V of V_{dep}. In case that V_{dep} was adjusted to −13 V, an IPSC of a large width was generated. However, in case that a dipolar polarization layer was included, EPSC was generated. Particularly, a thickness of the charge capture layer was 10 nm, and a thickness of the dipolar polarization layer was 40 nm ((b): Embodiment 4), EPSC was generated at −9 V of Vₚₒₜ, and IPSC was generated at −14 V of V_{dep}. In addition, in case that a thickness of the charge capture layer was 5 nm, and a thickness of the dipolar polarization layer was 70 nm ((c): Embodiment 1), EPSC was generated at −12 V of Vₚₒₜ, and IPSC was generated at −21 V of V_{dep}.

As above, a heterojunction gate insulating layer of the present disclosure may be provided to improve synaptic characteristics of a single-polarity driven synaptic transistor, and thicknesses of the charge capture layer and the dipolar polarization layer may be adjusted to further improve the synaptic characteristics.

### Experimental Example 3. Synaptic Characteristics Depending on a Pulse Width of a Single-Polarity Driven Synaptic Transistor

FIG. 8 illustrates synaptic characteristics according to a pulse width of a single-polarity synaptic transistor according to one embodiment of the present disclosure. Referring to FIG. 8, a gate pulse width of the same single-polarity driven synaptic transistor provided with a dipolar polarization layer including pH1D3 (Embodiment 2) was increased to increase both the increase and decrease of conductivity of a semiconductor channel layer. This indicates that by adjusting a gate pulse width of the single-polarity driven transistor, the conductivity is adjusted to a wider width in the same synapse device provided with the same heterojunction gate insulating layer.

### Experimental Example 4. Durability Characteristics Under Repetitive Cycles of Single-Polarity Driven Synaptic Transistor

In FIG. 9, it is shown that the single-polarity driven synaptic transistor including the heterojunction gate insulating layer of Embodiment 1 of the present disclosure operates stably with high reliability even after numerous repeated cycles. Referring to FIG. 9, it could be reliably confirmed that due to high breakdown voltage characteristics of the charge capture layer manufactured according to the present disclosure, the device operates stably even under repeated cycles of gate pulses with different amplitudes.

### Experimental Example 5. Verification of Chemical Composition of Single-Polarity Driven Synaptic Transistor

FIG. 10 illustrates Fourier transform infrared (FT-IR) spectra of the dipolar polarization layers with different compositions of 2-hydroxyethylacrylate (HEA) in the single-polarity driven synaptic transistor according to one embodiment of the present disclosure. Referring to the Fourier transform infrared spectra (FT-IR) of the single-polarity driven synaptic transistors according to Embodiments 1 through 3 and Comparative Example 1 described in FIG. 10, it was confirmed that the monomers of 2-hydroxyethyl acrylate (HEA) and di(ethyleneglycol)divinylether (DEGDVE) consisting of the heterojunction gate insulating layer were successfully polymerized. In addition, it was confirmed that the chemical composition of the monomers could be precisely controlled by adjusting the flow rates.

While certain embodiments of the present disclosure have been described in detail above, anyone ordinarily killed in the art to which the present disclosure pertains shall appreciate that the embodiments are to describe the present disclosure in detail, the present disclosure is not limited thereto, and there may be a variety of modifications and permutations in the technical scope of the present disclosure. Simple modifications to variations of the present disclosure are all considered to fall in the scope of the present disclosure, and the specific scope of the present disclosure will be clearly defined by the claims.

What is claimed is:

1. A heterojunction gate insulating layer comprising:
a dipolar polarization layer capable of polarization alignment; and
a charge capture layer formed on one side of the dipolar polarization layer and configured to capture a hole or an electron.

2. The heterojunction gate insulating layer of claim 1,
wherein the dipolar polarization layer is formed of a ferroelectric material.

3. The heterojunction gate insulating layer of claim 2,
wherein the dipolar polarization layer is selected from poly(vinylidene fluoride) (PVDF) and a copolymer thereof, or polymers including a hydroxyl group (—OH) or a nitrile group (—CN).

4. The heterojunction gate insulating layer of claim 1,
wherein the dipolar polarization layer comprises p(HEA-co-DEGDVE), and
wherein a molar ratio of di(ethylene glycol)divinyl ther (DEGDVE):2-hydroxyethylacrylate (HEA) comprised in the p(HEA-co-DEGDVE) is 1:1 to 1:10.

5. The heterojunction gate insulating layer of claim 1,
wherein a thickness of the dipolar polarization layer is greater than or equal to 20 nm and less than or equal to 200 nm.

6. The heterojunction synaptic gate insulating layer of claim 1,
wherein the charge capture layer is selected from poly(1,3,5-trimethyl-1,3,5-trivinyl cyclotrisiloxane (pV3D3), poly(2-vinylnaphthalene) (PVN), polystyrene (PS), alpha-methyl styrene (PαMS), poly(divinylbenzene) (pDVB), poly(ethylene glycol dimethacrylate) (pEGDMA), poly(1,4-butanediol diacrylate) (pBDDA), poly(3,3,4,4,5,5,6,6,7,7,8,8,9,9,10,10,10-heptadecafluorodecyl methacrylate) (pPFDMA), or a combination thereof.

7. The heterojunction gate insulating layer of claim 1,
wherein a thickness of the charge capture layer is greater than or equal to 5 nm and less than or equal to 25 nm.

8. A single-polarity driven synaptic transistor comprising:
a substrate;
a gate electrode disposed on the substrate and applied with a voltage;
a heterojunction gate insulating layer formed on the gate electrode;
a semiconductor channel layer formed on one side of the heterojunction gate insulating layer; and
a source and drain electrodes laminated on the semiconductor layer, spaced apart from each other and having at least a portion making contact with the gate insulating layer and the semiconductor channel layer,
wherein the heterojunction gate insulating layer comprises a dipolar polarization layer capable of polarization alignment; and a charge capture layer formed on one side of the dipolar polarization layer and configured to capture a hole or an electron.

9. The single-polarity driven synaptic transistor of claim 8,
wherein the dipolar polarization layer comprises a ferroelectric material.

10. The single-polarity driven synaptic transistor of claim 8,
wherein the semiconductor channel layer is an N-type semiconductor or a P-type semiconductor.

11. The single-polarity driven synaptic transistor of claim 8,
wherein the single-polarity driven synaptic transistor is configured to control a voltage applied to the gate electrode and control flow of a hole to the drain electrode through the gate insulating layer and the semiconductor channel layer to implement excitatory postsynaptic current (EPSC) or inhibitory postsynaptic current (IPSC).

12. The single-polarity driven synaptic transistor of claim 8,
wherein in case that a voltage of greater than or equal to −12 V and less than or equal to −3 V is applied to the gate electrode, a hole inside the semiconductor channel layer is accumulated due to orientation of the dipolar polarization layer to implement excitatory postsynaptic current (EPSC), and
wherein in case that a voltage of greater than or equal to −30 V and less than or equal to −20 V is applied to the gate electrode, a hole is captured from the semiconductor channel layer into the charge capture layer or at an interface between the charge capture layer and the dipolar polarization layer to implement inhibitory postsynaptic current (IPSC).

13. The single-polarity driven synaptic transistor of claim 8,
wherein as a pulse width applied to the gate electrode increases, both increase and decrease in conductivity of the semiconductor channel layer increase.

14. The single-polarity driven synaptic transistor of claim 8,
wherein a single-polarity driven repetitive cycle is formed, the single-polarity driven repetitive cycle operating stably even during repeated cycles of electrical pulses applied to the gate electrode.

15. An artificial sensory system comprising a single-polarity driven synaptic transistor of claim 8.
